(19) United States
(12) Patent Application Publication
(10) Pub. No.: US 2008/0292781 A1
(43) Pub. Date: Nov. 27, 2008

(54) Method for Monitoring a Plasma, Device for Carrying Out this Method, Use of this Method for Depositing a Film Onto a Pet Hollow Body

(75) Inventors: Jean-Michel Rius, Octeville sur Mer (FR); Guy Feuilloley, Octeville sur Mer (FR)

Correspondence Address: SUGHRUE MION, PLLC, 2100 PENNSYLVANIA AVENUE, N.W., SUITE 800, WASHINGTON, DC, 20037, US

(73) Assignee: SIDEL PARTICIPATIONS, OCTEVILLE-SUR-MER (FR)

(21) Appl. No.: 12/091,933

(22) PCT Filed: Oct. 26, 2006
(86) PCT No.: PCT/FR2006/002412

§ 371 Date: Apr. 28, 2008

(30) Foreign Application Priority Data
Oct. 27, 2005 (FR) 0510998

(51) Int. Cl. C23C 16/52; B05C 11/00

(52) U.S. Cl. 427/8; 118/712

(57) ABSTRACT

The invention relates to a method for monitoring the composition of a plasma, this plasma being generated from determined precursors for depositing a film onto a polymer material. This method involves receiving light intensities emitted by the plasma and comprises: a step for selecting a first reference wavelength range that is selected within a plasma emission spectral region in which no significant signal of a parasitic chemical species can exist, i.e. which is not part of the determined precursors and which is thus normally not present in the plasma and whose presence in the plasma influences the nature of the deposited film; a step for selecting a second wavelength range which is selected within a plasma emission spectral region in which a significant signal of a parasitic chemical species is likely to exist; a step for simultaneously acquiring light intensities emitted by the plasma in each of the two selected wavelength ranges emitted by the plasma in each of the two selected wavelength ranges, and; a step for calculating, on the basis of these light intensities, at least one monitoring coefficient.

The invention relates to the technical field of polymer products coated by plasma deposition with a thin layer on at least one of their faces.

The invention applies in particular, but not exclusively, to plasma deposition in containers made of a polymer material, such as bottles made of PET (polyethylene terephthalate).

The conventional polymer materials employed for the manufacture of bottles or containers, such as PET, all have a relative permeability to oxygen and to carbon dioxide. What is more, some molecules, which contribute to aromas, may be adsorbed on the wall of the containers and eventually diffuse through these walls.

Quite recently, it has been proposed to use plasmas for depositing barrier layers on polymer containers, such as bottles, which have to contain products sensitive to oxidation (beers, fruit juices, carbonated drinks) so as to increase the impermeability of these containers to certain gases, such as oxygen and carbon dioxide, and consequently to extend their shelf life.

These barrier layers plasma-deposited in polymer containers are, for example, of the organic (carbon) or inorganic (silica) type.

Whatever their chemical nature, it is of great industrial importance to be able to check the quality of these barrier layers.

The use of optical emission spectroscopy has been mentioned for studying the reactions within the plasma and to check the films deposited by CVD (U.S. Pat. No. 6,117,243, column 1, lines 28 to 37). Document U.S. Pat. No. 5,521,351 illustrates (FIG. 7) and mentions (column 7, lines 38 to 45) the fitting of an optical fiber inside a bottle, during plasma deposition, this optical fiber being connected to an optical emission spectrometer. However, this document U.S. Pat. No. 5,521,351 is silent as to the measured parameters. In addition, fitting the fiber in the container containing the plasma inevitably results in deposition on the optical fiber itself and eventually to said fiber being fouled.

The Applicant was tasked with developing a technique for monitoring the composition of plasmas that allows the quality of the films deposited by these plasmas to be predetermined.

The Applicant was tasked with determining whether this monitoring technique may allow samples to be taken but also provides continuous control, and to do so on machines with a high production rate.

Document EP 0 299 752 discloses a process for the plasma deposition of a thin film on a surface of a substrate in which the optical emission of the plasma is monitored and controlled. According to this invention, the intensities of two emission lines within different wavelength bands corresponding to two species present in the plasma are detected, the intensities being normalized and the ratio then being compared with a reference value. However, the species are selected from species that are contained in the precursors and are therefore necessarily present in the plasma being monitored. Depending on the value of this ratio, which allows the preponderance of one or other of the species and therefore the quality of the film deposited, to be determined, the flow rate of the precursors injected into the volume where the plasma is generated is then modified.

However, to form an internal layer in the internal volume of a container it is necessary to place the internal volume of the container at a relatively low pressure during generation of the plasma. This internal pressure, requiring the formation of a sealed contact between the container and the plasma-generating machine, may result in leaks occurring, leading to ingress of air into the internal volume of the container, which leaks are liable to impair the good quality and homogeneity of the internal layer deposition owing to the introduction of undesirable species.

The process in document EP 0 299 752 does not allow the presence of foreign elements in the plasma to be checked nor, if the plasma is formed inside a container, does it allow the detection of a leak and of poor sealing between the internal volume of the container and the ambient air, which leak is liable to result in the formation of an inhomogeneous internal layer or a layer having cracks, because only chemical species intentionally injected into the plasma are monitored.

The object of the present invention is more particularly to detect the presence of a leak in the internal volume of the container during plasma generation.

For this purpose, the invention relates, according to a first aspect, to a method of monitoring the composition of a plasma, this plasma being generated from defined precursors for the deposition of a film onto a polymer material, this method comprising the measurement of light intensities emitted by the plasma, this method being characterized in that it comprises:
a step of selecting a first wavelength range, called reference range, which is selected from a region of the plasma emission spectrum in which no significant signal characteristic of what is called a parasitic chemical species, that is to say one that does not form part of said defined precursors and is therefore normally not present in the plasma, and the presence of which in the plasma influences the nature of the film deposited, can exist;
a step of selecting a second wavelength range which is selected from a region of the plasma emission spectrum in which a significant signal characteristic of a parasitic chemical species is likely to exist;
a step of simultaneously acquiring the light intensities emitted by the plasma in each of the two selected wavelength ranges; and

a step of calculating, from said light intensities, at least one monitoring coefficient.

In a first implementation, the two wavelength ranges have very small spectral widths and correspond substantially to two wavelengths λ₁ and λ₂.

At least one monitoring coefficient is a function of the difference between the emission intensities for said first and second wavelengths.

More particularly, at least one monitoring coefficient is a function of the difference between the emission intensities for said first and second wavelengths, said difference being normalized with the value of the emission intensity for the first or second wavelength.

In a second embodiment, the two wavelength ranges each have a spectral width and correspond to two bandwidths.

At least one monitoring coefficient is a function of the difference between the emission intensities for said first and second bandwidths.

More particularly, at least one monitoring coefficient is a function of the difference between the emission intensities for said first and second bandwidths, said difference being normalized to the emission intensity for the first or second bandwidth.

The selected parasitic chemical species likely to generate a significant signal in the second wavelength range is for example a species that is not desired in the film to be plasma deposited on the polymer material.

In certain embodiments, the gaseous precursor is selected from alkanes, alkenes, alkynes and aromatics, said parasitic chemical species likely to generate a significant signal in the second wavelength range being one of the constituents of air.

In one particular embodiment, the precursor is based on acetylene, the parasitic chemical species being nitrogen. The monitoring method thus makes it possible, for example, to detect an air leak into the plasma deposition installation.

Advantageously, the wavelength ranges are selected from that part of the emission spectrum lying between approximately 800 nanometers and approximately 1000 nanometers.

The invention relates, according to a second aspect, to the application of the method of monitoring the composition of a plasma such as that presented above, the plasma being a microwave plasma for depositing a film onto a hollow body made of PET.

The invention relates, according to a third aspect, to a device for implementing the method of monitoring the composition of a plasma as presented above, this device comprising at least one detector for detecting the light intensity emitted by the plasma, and microwave electromagnetic excitation means for generating a plasma in a microwave cavity, this cavity containing a vacuum chamber, this vacuum chamber being intended to house a container made of polymer material, for the deposition of a film inside this container.

Advantageously, the detector(s) are placed against the cavity, the light intensities being measured through the container and through the wall of the vacuum chamber.

Other aspects, objects and advantages of the invention will become apparent over the course of the following description of embodiments, which description is given in conjunction with the appended drawings in which:

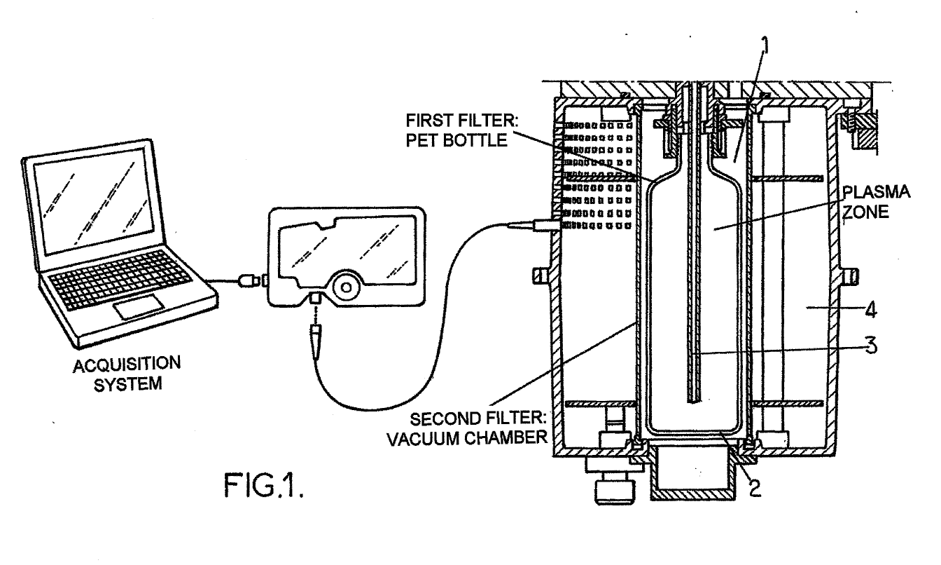

FIG. 1 is a cross-sectional view of part of a machine sold by the Applicant under the name Actis®, this FIG. 1 also showing a device for implementing the method according to the invention and connected to the Actis® machine;

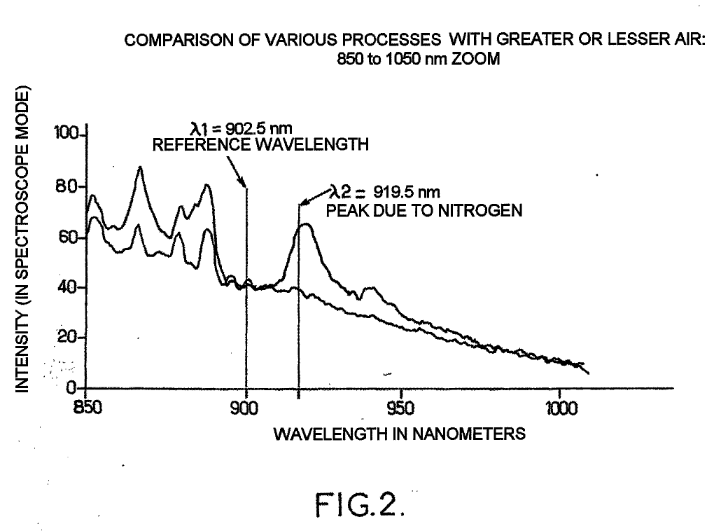

FIG. 2 shows several optical emission spectra obtained for bottles treated according to the Actis® method of the Applicant, two particular wavelengths being selected for calculating a monitoring coefficient according to one embodiment of the present invention;

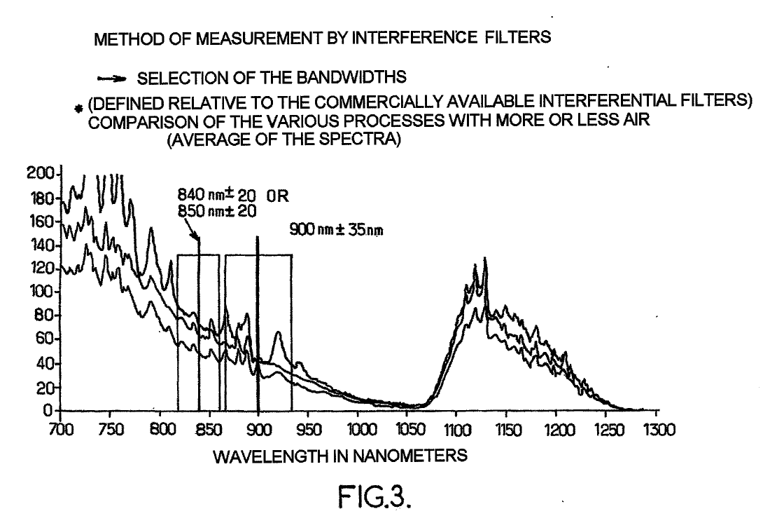

FIG. 3 shows several optical emission spectra obtained for bottles treated according to the Actis® method of the Applicant, two wavelength ranges being selected for calculating a monitoring coefficient, according to a second embodiment of the invention.

The following detailed description will be given with reference to the plasma deposition of a thin layer of amorphous carbon via a technique of the Applicant, this technique being known by the name Actis®.

However, it should be understood that this is merely one example of how the method according to the invention is implemented.

The following detailed description will be given with reference to the deposition of a film on bottles or bottle preforms.

It should be understood however that the method may be implemented during plasma deposition on a polymer material for the production of containers other than bottles, namely molded, injection-molded, pultruded, blow-molded and thermoformed hollow bodies.

The description firstly refers to FIG. 1. As described in document WO 99/49991 of the Applicant, a machine (of the Actis® type) comprises at least one vacuum chamber 1 defined by walls made of a material transparent to microwaves, for example quartz.

This vacuum chamber 1 is closed by a removable mechanism for installing the object to be treated, here a bottle or a bottle preform 2, and for removing it after treatment.

This vacuum chamber 1 is connected to pumping means (not shown).

An injector 3 is provided for injecting at least one gaseous precursor into the bottle 2, said injector being connected to a reservoir, a mixer or a bubbler (these not being shown).

The vacuum chamber 1 is placed in a cavity 4 having conducting walls, for example metal walls, said cavity being connected to a microwave generator via a waveguide.

If it is desired to deposit carbon on the internal surface of the bottle or bottle preform, the gaseous precursor may be selected from alkanes (for example methane), alkenes, alkynes (for example acetylene) and aromatics.

The pressure within the reaction chamber, consisting of the bottle or bottle preform 2, must be low, preferably below 10 mbar and especially between 0.01 and 0.5 mbar.

To prevent the bottle or bottle preform deforming, the pressure difference between the inside and the outside of the bottle (or preform) is low, a vacuum being created inside the vacuum chamber.

Sealing is also provided at the neck of the bottle or preform, poor sealing possibly resulting in the occurrence of leaks between the internal volume of the bottle and the external air.

By means of these arrangements, a plasma is created in the preform (or bottle) which itself constitutes the reaction chamber, thus reducing the risk of forming a plasma on the outer surface of the bottle (or preform), the transparent walls of the vacuum chamber thus not being fouled.

To give an example, for UHF excitation at 2.45 GHz and a microwave power of 180 W, a carbon film can be deposited with a growth rate of around 250 angstroms per second with an acetylene flow rate of 80 sccm under a pressure of 0.25 mbar, a residual pressure of 0.2 mbar being maintained inside the bottle (or preform), a residual pressure of 50 mbar inside the vacuum chamber and outside the bottle (or preform) being sufficient to prevent deformation of said bottle (or said preform) during carbon deposition.

For a 390 ml (13 oz; 26.5 g) PET bottle, the precursor is for example injected after a time T₁ of around 1.5 seconds, time T₁ being called the flushing time during which the bottle or bottle preform is flushed with a stream of acetylene, the pressure being gradually reduced down to a value of around 0.25 mbar. Next, over an entire deposition time T₂, of around 1.2 seconds, an electromagnetic field is applied in the bottle or preform, the precursor being acetylene injected at a flow rate of around 100 sccm, the microwave power being about 200 W for a frequency of 2.45 GHz, the carbon thickness obtained being around 40 nanometers.

The description now refers to FIG. 2.

The present invention relates in general to a method of monitoring the composition of a plasma, this plasma being generated from defined precursors for the deposition of a film onto a polymer material, this method comprising the measurement of light intensities emitted by the plasma.

In a first implementation of the method, two wavelengths λ₁ and λ₂ are fixed, the first wavelength λ₁ being a reference wavelength and selected from a wavelength range in which no significant peak characteristic of a parasitic chemical species with regard to the film to be deposited can exist. The term “parasitic species” is understood to mean a chemical species which does not form part of the precursors, which is not normally present in the plasma and the presence of which in the plasma influences the nature of the film deposited. The parasitic chemical species is, according to one embodiment of the invention, a species that is not desired in the film to be plasma-deposited on the polymer material.

In the example illustrated in FIG. 2, this wavelength λ₁, is 902.5 nanometers. In general, and as will be explained in relation to FIG. 3, the method according to the invention provides a step of selecting a first wavelength range, called reference range, which is selected from a region of the plasma emission spectrum in which no significant signal characteristic of a parasitic chemical species can exist. According to the embodiment illustrated in FIG. 2, the reference wavelength range has a very small spectral width and corresponds approximately to the wavelength λ₁.

The first wavelength range is therefore selected from part of the plasma emission spectrum, the characteristics of which remain substantially constant and uniform in the presence both of a reference species and of a parasitic species, that is to say part of the spectrum that is not substantially modified in the presence of species likely to influence the nature of the layer of material deposited.

In contrast to λ₁, the second wavelength λ₂ is specifically dedicated to a chemical species that is not normally involved in the film deposition process, except when there is a problem. This chemical species may for example be a constituent whose concentration in the deposited film influences the properties of this film. In particular, this chemical species may have a deleterious effect on the barrier properties of the film or else its mechanical or optical properties. In other words, in general, and as will be explained in relation to FIG. 3, the method according to the invention provides a step of selecting a second wavelength range which is selected from a region of the plasma emission spectrum in which a significant signal characteristic of said parasitic chemical species is likely to exist, which signal is relatively pronounced depending on the concentration of the parasitic species in question. According to the embodiment illustrated in FIG. 2, the reference wavelength range has a very small spectral width and corresponds approximately to the wavelength λ₂.

In the example illustrated in FIG. 2, this wavelength λ₂ is 919.5 nanometers and emanates from nitrogen. The method according to the invention thus makes it possible in particular to detect the presence of an air leak into a plasma deposition installation, the parasitic chemical species selected then advantageously being selected from the constituents of air (nitrogen, oxygen, etc.).

The intensities of the two lines obtained for these wavelengths λ₁ and λ₂ are acquired simultaneously and a monitoring coefficient N is calculated from these two simultaneously recorded intensities. The fact that the acquisition takes place simultaneously makes it possible not only to factor out intensity variations due to pulsing of the plasma but also, among other things, variations that occur over the course of the deposition process taking place.

In the example shown in FIG. 2, this coefficient N is equal to (Iλ₂−Iλ₁)/Iλ₂, i.e. the difference between the intensities of the lines obtained for λ₂ and λ₁ divided by the intensity obtained for λ₂.

Thus, the method according to the invention also includes a step of simultaneously acquiring the light intensities emitted by the plasma in each of the two selected wavelength ranges and a step of calculating, from said light intensities, at least one monitoring coefficient.

This ratio is associated, for example using experimental correlation tables, with various properties of the deposited film, for example oxygen permeability of the coated bottle, carbon dioxide permeability of the coated bottle, film thickness, color of the film, composition of the film.

Preferably, said at least one monitoring coefficient is a function of the difference between the emission intensities for the first and second wavelengths λ₁ and λ₂.

Advantageously, the monitoring coefficient is a function of the difference between the emission intensities for said first and second wavelengths λ₁ and λ₂, which difference is normalized to the value of the emission intensity for the first or second wavelength.

It is thus possible, depending on the desired characteristics of the bottle, to determine a monitoring coefficient value or range of values and to detect a drift or an anomaly in the plasma deposition process, the rapid correction of this anomaly limiting the number of nonconforming bottles at will.

The description now refers to FIG. 3. In this second implementation of the method, two wavelength windows or ranges λ₁ and λ₂, each having a spectral width and corresponding to two bandwidths, are fixed, the first wavelength window λ₁ being a reference window and selected from a wavelength range in which no significant peak characteristic of a chemical species of interest in the film to be deposited exists, namely a wavelength range, called the reference range, which is selected from a region of the plasma emission spectrum in which no significant signal characteristic of a parasitic chemical species can exist.

In the example illustrated in FIG. 3, this wavelength window λ₁ is centered on 840 or 850 nanometers, with a width of 40 nanometers.

The second wavelength window λ₂ is, in contrast to λ₁, specifically dedicated to a chemical species involved in the film deposition process, namely in a wavelength range which is selected from a region of the plasma emission spectrum in which a significant signal characteristic of said parasitic chemical species is likely to exist.

In the example illustrated in FIG. 3, this wavelength window λ₂ is centered on 900 nanometers, with a width of 70 nanometers, and allows the nitrogen peaks at 870, 885 and 920 nanometers to be included.

The intensities U₁, U₂ of the two bandwidths obtained are acquired simultaneously and a monitoring coefficient N is calculated from these two simultaneously recorded intensities. As previously, the fact that the acquisition is carried out simultaneously makes it possible to factor out not only variations in intensity due to pulsing of the plasma but also, among other things, variations occurring over the course of the deposition process taking place.

In the example shown in FIG. 3, this coefficient N is equal to (U₂−U₁)/U₂, namely the difference between the intensities of the bandwidths divided by the intensity of the bandwidth centered on the second wavelength λ₂.

Preferably, the monitoring coefficient is a function of the difference between the emission intensities for said first and second bandwidths.

More precisely, the monitoring coefficient is a function of the difference between the emission intensities for said first and second bandwidths, said difference being normalized to the emission intensity for the first or second bandwidth.

This ratio is associated, for example using experimental correlation tables, with various properties of the deposited film, for example the oxygen permeability of the coated bottle, the carbon dioxide permeability of the coated bottle, the film thickness, the color of the film and the composition of the film.

Thus, it is possible, according to the desired characteristics of the bottle, to determine a monitoring coefficient value or range of values and to detect a drift or an anomaly in the plasma deposition process, the rapid correction of this anomaly limiting the number of nonconforming bottles at will.

The Applicant has found that by working in the spectral range from approximately 800 nanometers to approximately 1000 nanometers, it is possible to eliminate the impact of the color of an amorphous carbon layer, such as for example deposited by the Actis® process, and the color of the bottle, the detectors thus being able to be placed against the cavity 4 having conducting walls, the plasma being seen through the wall of the bottle and through the walls of the vacuum chamber 1.

In an advantageous embodiment, the spectrometers are fixed to each cavity of the production machine, optical or electronic multiplexing enabling several plasmas to be controlled.

In one embodiment, an optical fiber is placed in the precursor gas injector and consequently protected from being fouled, this embodiment making it possible to eliminate the filter due to the wall of the bottle and to the walls of the vacuum chamber 1, the wavelengths λ₁ and λ₂ of the lines or bandwidths thus being able to be chosen in the near UV.

According to a preferential application of the method of monitoring the composition of a plasma, the plasma is a microwave plasma for depositing a film onto a hollow body made of PET.

The present invention also relates to a device for implementing the method of monitoring the composition of a plasma according to the invention, said device comprising at least one detector for detecting the light intensity emitted by the plasma, and microwave electromagnetic excitation means for generating a plasma in a microwave cavity, this cavity containing a vacuum chamber, this vacuum chamber being intended to house a container made of polymer material, for the deposition of a film inside this container.

Preferably, the detector(s) are placed against the cavity, the light intensities being measured through the container and through the wall of the vacuum chamber.

The method according to the invention offers many advantages.

It makes it possible to detect as soon as possible an anomaly in the operation of the production machine, for example an air leak.

If this machine can operate at a high production rate, as is the case for the machines of the Applicant, the method according to the invention makes it possible to detect any maladjustment of the manufacturing parameters and to limit scrap.

Thus, depending on the value of the ratio calculated according to the invention, it is decided whether the internal layer of the container has been formed correctly and whether the container formed has to be scrapped and removed from the production line.

The object of the method according to the present invention is mainly to monitor the quality of the plasma formed and not to consequently modify on a case by case basis the parameters for adjusting the plasma. However, when it is found that a large number of containers in succession have been scrapped, then it is conceivable to stop the operation of the plasma-generating machine and consequently modify the plasma generation parameters.

According to the invention, it is also decided with what spread, relative to the reference value, the nature of the internal layer may be considered as being acceptable according to the nature of the container and of its characteristics.

If a leak is detected according to the present invention, the container is either removed from the production line or it is considered that the influence of the leak on the plasma deposition of the internal layer is only slightly modified according to the value of the ratio and the acceptable spread.

Finally, the method according to the invention is inexpensive. Its implementation does not necessarily involve altering the structure of the existing production machines.

1. A method of monitoring the composition of a plasma, said plasma having a plasma emission spectrum, and being generated from at least one defined gaseous precursor for a deposition of a film onto a polymer material, said method comprising at least one measurement of light intensities emitted by said plasma, said method comprising:
a step of selecting a first wavelength range as a reference range, which is selected from a region of said plasma emission spectrum in which no significant signal can exist, which is characteristic of a parasitic chemical species, that does not form part of said defined precursors and is therefore normally not present in said plasma, and the presence of which in said plasma influences the nature of said film when deposited;
a step of selecting a second wavelength range which is selected from a region of said plasma emission spectrum in which a significant signal characteristic of a parasitic chemical species is likely to exist;
a step of simultaneously acquiring the light intensities emitted by said plasma in each of said first and second selected wavelength ranges; and
a step of calculating, from said light intensities, at least one monitoring coefficient.

2. The method of monitoring the composition of a plasma as claimed in claim 1, wherein said two wavelength ranges have very small spectral widths corresponding substantially to two wavelengths λ₁ and λ₂.

3. The method of monitoring the composition of a plasma as claimed in claim 2, wherein at least one monitoring coefficient is a function of a difference between measured emission intensities for said first and second wavelengths λ₁ and λ₂.

4. The method of monitoring the composition of a plasma as claimed in claim 2, wherein at least one monitoring coefficient is a function of a difference between measured emission intensities for said first and second wavelengths λ₁ and λ₂, said difference being normalized with a value of an emission intensity for one of said first and second wavelengths.

5. The method of monitoring the composition of a plasma as claimed in claim 1, wherein said first and second wavelength ranges each have a spectral width and correspond to a first and second bandwidths respectively.

6. The method of monitoring the composition of a plasma as claimed in claim 5, wherein at least one monitoring coefficient is a function of a difference between measured emission intensities for said first and second bandwidths.

7. The method of monitoring the composition of a plasma as claimed in claim 5, wherein at least one monitoring coefficient is a function of a difference between measured emission intensities for said first and second bandwidths, said difference being normalized to said measured emission intensity for one of said first and second bandwidths.

8. The method of monitoring the composition of a plasma as claimed in claim 1, wherein said parasitic chemical species likely to generate said significant signal in said second wavelength range is a species that is not desired in said film to be plasma deposited on said polymer material.

9. The method of monitoring the composition of a plasma as claimed in claim 1, wherein said at least one gaseous precursor is selected from alkanes, alkenes, alkynes and aromatics, said parasitic chemical species likely to generate a significant signal in said second wavelength range being one of the constituents of air.

10. The method of monitoring the composition of a plasma as claimed in claim 9, wherein said gaseous precursor is based on acetylene, said parasitic chemical species being nitrogen.

11. The method of monitoring the composition of a plasma as claimed in claim 9, wherein said gaseous precursor is based on acetylene, said parasitic chemical species being oxygen.

12. The method of monitoring the composition of a plasma as claimed in claim 1, wherein said selected wavelength ranges are selected from a part of said plasma emission spectrum lying between approximately 800 nanometers and approximately 1000 nanometers.

13. The method of monitoring the composition of a plasma as claimed in claim 1, wherein said plasma is a microwave plasma for depositing a film onto a hollow body made of PET.

14. A device for implementing the method of monitoring the composition of a plasma as claimed in claim 1, characterized in that it comprises at least one detector for detecting the light intensity emitted by the plasma, and microwave electromagnetic excitation means for generating a plasma in a microwave cavity, this cavity containing a vacuum chamber, this vacuum chamber being intended to house a container made of polymer material, for the deposition of a film inside this container.

15. The device as claimed in claim 14, characterized in that the detector(s) are placed against the cavity, the light intensities being measured through the container and through the wall of the vacuum chamber.
